(19) United States
(12) Patent Application Publication
(10) Pub. No.: US 2010/0275973 A1
(43) Pub. Date: Nov. 4, 2010

(54) HIGH EFFICIENCY PHTOVOLTAIC PANEL WITH THERMAL FEATURE

(76) Inventor: Richard E. Carnation, Windsor, CA (US)

Correspondence Address: Bay Area Technology Law Group PC, Suite 404, 500 Sansome Street, San Francisco, CA, 94111, US

(21) Appl. No.: 12/719,057

(22) Filed: Mar. 8, 2010

(51) Int. Cl. H01L 31/058

(52) U.S. Cl. 136/248

(57) ABSTRACT

A device for the generation of electricity and for imparting thermal energy to a fluid. The device is composed of a panel of photovoltaic materials having a top surface which, when in use, is exposed to ambient solar radiation and a base for supporting the panel of photovoltaic materials. A plurality of micro channels are positioned within the base and in thermal contact with the photovoltaic material. The channels have open receiving ends and open discharge ends and are sized and positioned to receive a fluid at their receiving ends and to discharge the fluid at their discharging ends for transferring thermal energy from the bottom surface of the panel of photovoltaic materials to the fluid as the fluid travels within the channels.

### TECHNICAL FIELD

The present invention is directed to a device capable of being employed with a panel of photovoltaic cells in order to make use of what would otherwise be waste energy for heating a fluid passing adjacent the panel. Not only does the present invention enable one to make use of energy which otherwise would have been wasted, but the efficiency of the photovoltaic cells is greatly improved.

### BACKGROUND OF THE INVENTION

Despite the inherent costs associated with the purchase and installation of photovoltaic cells, their use is widespread and growing. Such devices provide a clean source of electrical energy and are thus quite appealing to those having environmental concerns. In addition, there are those that are sensitive to the varying costs of electricity and hydrocarbon fuels, the latter oftentimes being unreliable as a result of geopolitical conflicts unrelated to supply side economics.

Photovoltaic cells can be a number of configurations. As an example, reference is made to FIG. 1 showing a cut away perspective view of a typical photovoltaic cell. Specifically, this cell is provided with cover glass 1, an antireflective coating 2, a contact grid 3, N-type silicone and P-type silicone as layers 4 and 5, respectively, all supported by backing 6. In operation, the photovoltaic cell of FIG. 1 is exposed to sunlight on its top side where cover glass 1 is positioned to maximize the receipt of ambient sunlight. Backing 6 is attached to a suitable support generally positioning photovoltaic cell 10 on a roof top or similar elevated location to minimize shading from other structures or trees. Ground mounted systems are also utilized where clear open space is available.

A limiting factor which reduces the efficiency of photovoltaic cell 10 is that, during normal operation, thermal energy is created. Roughly speaking, the higher the thermal energy build up, the lower is the efficiency of the photovoltaic cell.

In addition to the above, if one was to employ a photovoltaic cell in order to heat a liquid, the electricity created from the cell would be employed to drive an electric heater, which in turn, would be used to heat the appropriate fluid. Thus, if one wished to use photovoltaic cell 10 to heat water for residential, commercial or industrial usage, such as for dishwashing, showering, cleaning, disinfecting or bathing, the appropriate electric heater would be powered by the cell which in turn would heat the water. The thermal energy created by this cell would be waste energy dissipated at the photovoltaic cell's location.

It is thus an object of the present invention to provide a photovoltaic cell which operates more efficiently than commonly employed cells by drawing away from the cell thermal energy which would otherwise reduce its efficiency.

It is yet a further object of the present invention to provide a photovoltaic cell which can be used not only to create electrical energy, but also be used to heat a circulating fluid in order to maximize the total energy output from such a device.

It is still yet a further object of the present invention to provide a device capable of being appended to a preexisting photovoltaic cell to convert the cell for transferring thermal energy to a circulating fluid associated therewith.

These and further objects will be more readily apparent when considering the following disclosure and appended claims.

### SUMMARY OF THE INVENTION

A device for the generation of electricity and for imparting thermal energy to a fluid, said device comprising a panel of photovoltaic material having a top surface, which when in use, is exposed to ambient solar light radiation, and a bottom surface in uniform and contiguous contact with a base for supporting said panel of photovoltaic material, said base comprising self-supporting extruded sheeting having a plurality of channels being uniformly sized an spaced between layers of electrically insulative membranes, said channels further being coextensive with said photovoltaic material, said channels having open receiving ends and open discharging ends, said channels being sized and positioned to receive said fluid at said receiving ends and to discharge said fluid at said discharging ends and to transfer thermal energy from said bottom surface to said fluid as said fluid travels within said channels thus reducing the operational temperature of the photovoltaic panel. Circulating fluid would discharge thermal energy at a heat sink such as a pool, spa, water tank, lake, pond, water feature, radiator or some other cooling source.

### BRIEF DESCRIPTION OF THE FIGURES

FIG. 1 is a perspective view of a typical photovoltaic cell useful in providing the basis for the present invention.

FIG. 2 is a perspective view of the present invention employed with a photovoltaic cell such as depicted in FIG. 1.

FIG. 3 is a cross-sectional view of a portion of the invention taken along line 3-3 of FIG. 2.

### DETAILED DESCRIPTION OF THE INVENTION

Novel features which are characteristic of the invention, as to organization and method of operation, together with further objects and advantages thereof will be better understood from the following description considered in connection with the accompanying drawings, in which preferred embodiments in the invention are illustrated by way of example. It is to be expressly understood, however, that the drawings are for illustration description only and are not intended as definitions of the limits of the invention. The various features of novelty which characterize the invention are recited with particularity in the claims.

There has been broadly outlined the more important features of the invention in the summary above and in order that the detailed description which follows may be better understood, and in order that the present contribution to the art may be appreciated. There are, of course, additional features of the invention that will be described hereinafter and which will form additional subject matter of the claims appended hereto. Those skilled in the art will appreciate the conception upon which this disclosure is based which readily may be utilized as a basis for the designing of other structures, methods and systems for carrying the several purposes of the present invention. It is important, therefore, that the claims be regarded as including such equivalent constructions insofar as they do not depart from the spirit and scope of the present invention.

As noted in the Summary of the Invention recited above, the subject of this disclosure is an arrangement for improving the efficiency of a photovoltaic panel by importing thermal energy created during normal operation of the panel to a circulating fluid. As an added benefit the thermal energy can be employed at a heat sink to enable one to maximize the energy output from such a cell. With this in mind it should be readily apparent that the present invention could be used with any type of photovoltaic cell including various paints and thin films known in the art Reference to a specific photovoltaic cell is illustrative purposes only and is not to be seen as limiting the present invention thereto.

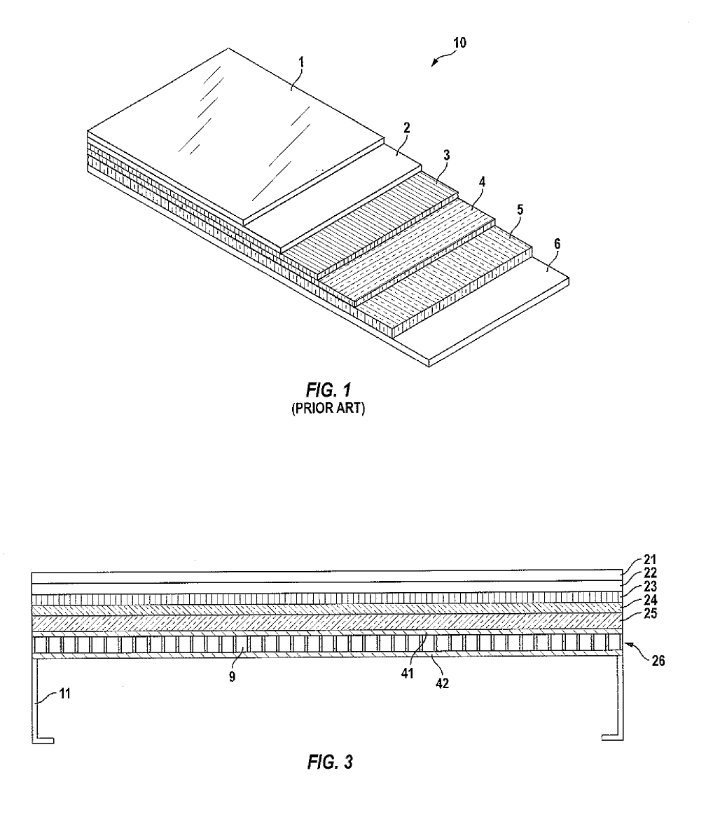

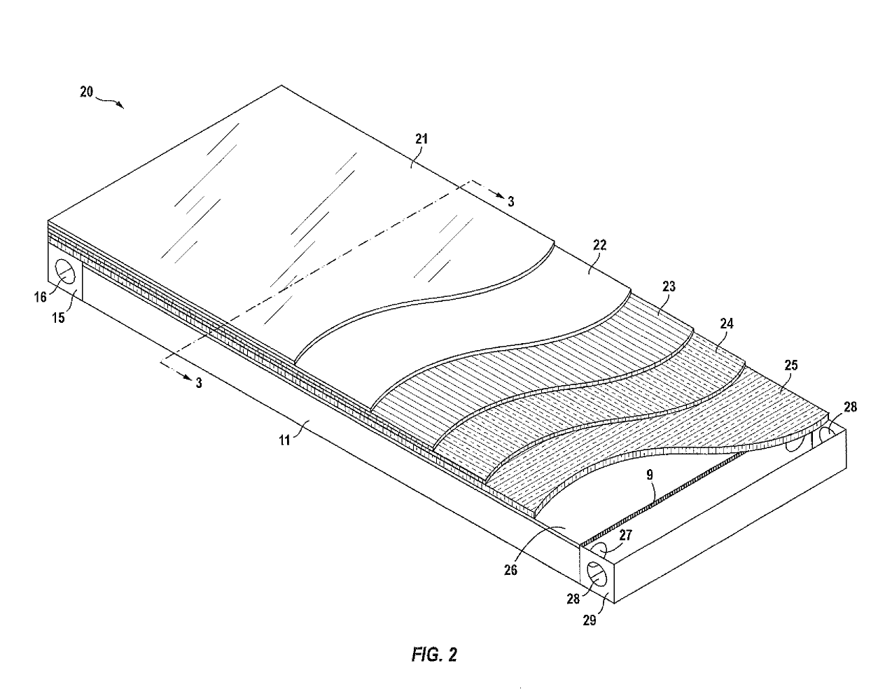

The device of the present invention can be more readily appreciated by initially referring to FIG. 2. As was the case with FIG. 1, photovoltaic cell 20 is imparted with optional cover glass 21, anti-reflective coating 22, contact grid 23, N type silicon 24 and P type silicon 25. Element 26 constitutes the supporting base of photovoltaic cell 20 which contains a plurality of channels as depicted in FIG. 3. These channels ideally extend parallel to one another and cover substantially the full extent of the bottom surface of photovoltaic cell 20. Again, the channels are sandwiched between sheets that function as this base or backing for the photovoltaic cell as will be described in more detail hereinafter.

Turning once again to FIG. 2, in operation, circulating fluid can be introduced to header 15 through opening 16. Fluid so introduced can pass within plurality of channels 9 (FIG. 3) within backing layer 26. As fluid passes along these channels, it is discharged at downstream end 8 through header 29 via openings 28. During the passage of fluid through channels 9, thermal energy is received from the photovoltaic cell which, as noted above, generates thermal energy through its normal employment as a generator of electrical energy from ambient solar light radiation. Fluid passing through channels 9 not only receive thermal energy to be used elsewhere but also to improve the electrical production efficiency of the photovoltaic cell by drawing away heat which depresses the efficiency of the cell. The overall structure of FIG. 2 is completed by use of flame member 11 securing the upstream and downstream headers 15 and 29 and ensuring the planar conformance of base 26.

An important feature of the present invention is the use of base 26 comprised of a self-supporting member having sheeting layers 41 and 42 and a plurality of channels 9 sized and spaced between the sheeting layers which are electrically insulative membranes As noted previously, channels 9 are co-extensive with the photovoltaic material such that as fluids pass within channels 9, a uniform temperature profile is established throughout base 26. This is an important feature of the present invention as the prior art in suggesting fluid cooled photovoltaic cells, generally teach the use of serpentined piping or tubing creating uneven temperature profiling. Further, as the prior art suggests copper or similar tubing for this purpose, separate insulative barriers must be established to prevent short circuiting the photovoltaic cell as a result of its contact with such electrically conductive materials By contrast, base 26 is composed of material which is electrically insulative such as polypropylene or high density polyethylene sheeting which has been blown to create micro channels 9 so that the channel material is co-extensive with and of the same composition as that constituting sheeting materials 41 and 42 One such product suitable for use herein is available by Coroplast of Dallas, Tex. as described in the company's Technical Bulletin-CSS-03.3-9.3. Such sheeting material is available in 2 to 12 mm thicknesses having a density of approximately 450 to 2400 gms per square meter, sheeting thicknesses of approximately 0.0065 to 0.036″ and flute thicknesses of approximately 0.0065 to 0.025″. As such, as will be readily apparent, base 26 is composed of a multitude of micro channels 9 which can be box shaped or corrugated in cross section. Thus, the overall composite is extremely light in weight, non toxic, rigid and insulating thus minimizing the load imposed upon a roof or other supporting structure.

Although not shown, the present invention could be part of an overall system including a circulation pump, expansion tank and fluid lines directing heated fluid to its ultimate point of deployment. If one such fluid is water, it can be employed to add thermal energy to a water feature, such as a swimming pool, spa, hot tub and the like and also be directed to the interior of a suitable dwelling for use in dishwashing and bathing also commercial and industrial uses such as preheating and heating fluids for sanitization of wine tanks and other food processing machinery.

By increasing the efficiency of the photovoltaic panel to increase the production of electricity as well as produce thermal energy by cooling the panel, end users of the system can better utilize the solar area footprint of the solar panel No longer must an end user with limited space decide between either a photovoltaic panel for production of electricity or solar panel for the production of hot water as the two together work more efficiently than one by itself

The above disclosure is sufficient to enable one of ordinary skill in the art to practice the invention, and provides the best mode practicing the invention presently contemplated by the inventor. What is provided herein is a full and complete disclosure of the preferred embodiments of the invention. It is not desired to limit the invention to the exact construction, dimensions, relationships or operations as described. Various modifications, alternative constructions, changes and equivalents which readily occur to those skilled in the art may be employed as suitable, without department from the true spirit and scope of the invention. Such changes might involve alternative materials, components, structural arrangements, sizes, shapes, forms, functions, operational features or the like.

Therefore, the above description and illustration should not be considered as limiting the scope of the invention, which is defined by the appended claims.

What is claimed is:

1. A device for the generation of electricity and for imparting thermal energy to a fluid, said device comprising a panel of photovoltaic material having a top surface, which when in use, is exposed to ambient solar light radiation, and a bottom surface in uniform and contiguous contact with a base for supporting said panel of photovoltaic material, said base comprising self-supporting extruded sheeting having a plurality of channels being uniformly sized and spaced between layers of electrically insulative membranes, said channels further being coextensive with said photovoltaic material, said channels having open receiving ends and open discharging ends, said channels being sized and positioned to receive said fluid at said receiving ends and to discharge said fluid at said discharging ends and to transfer thermal energy from said bottom surface to said fluid as said fluid travels within said channels.

2. The device of claim 1 wherein a first header is positioned at the receiving end of said channels and a second header is positioned at the discharging end of said channels.

3. The device of claim 1 wherein said channels are arranged such that each channel extends parallel to other of said plurality of channels and said plurality of channels covering the substantial extent of said bottom surface.

4. The device of claim 1 wherein said sheeting comprises a member selected from the group consisting of polypropylene copolymers, cross-linked polyethylene and high density polyethylene.

5. The device of claim 1 wherein said channels are box-shaped or corrugated between said sheeting.

6. The device of claim 1 wherein said channels and sheeting are of the same composition.

7. The device of claim 1 wherein said base is approximately 2-12 mm in thickness

8. A method of generating electricity and imparting thermal energy to a fluid, said method comprising providing a panel of photovoltaic material having a top surface, which when in use, is exposed to ambient solar light radiation and a bottom surface in uniform and contiguous contact with a base for supporting said panel of photovoltaic material, said base comprising self supporting extruded sheeting having a plurality of channels being uniformly sized and spaced between layers of electrically insulative membranes, said channels further being co-extensive with the photovoltaic material, said channels receiving said fluid at said receiving ends and discharging said fluid at said discharging ends, while said top surface of said photovoltaic cells is exposed to ambient solar light radiation.

9. The method of claim 8 wherein said fluid is introduced to a first header positioned at the receiving ends of said channels and said fluid is received from the discharge ends of said channels within a second header.

10. A device for receiving thermal energy from a photovoltaic panel comprising a first header for receiving a fluid and for feeding said fluid to a plurality of longitudinally extending channels and a second header for receiving said fluid from said plurality of longitudinally extending channels, said plurality of longitudinally extending channels configured within a base, said base comprising self-supporting extruded sheeting, said channels being uniformly sized and spaced between layers of electrically insulative membranes sized for abutting and being co-extensive with said photovoltaic panel.
